(19) United States
(12) Patent Application Publication
(10) Pub. No.: US 2006/0246637 A1
(43) Pub. Date: Nov. 2, 2006

(54) Sidewall gate thin-film transistor

(75) Inventors: Apostolos T. Voutsas, Portland, OR (US); Paul J. Schuele, Washougal, WA (US)

Correspondence Address: SHARP LABORATORIES OF AMERICA, INC.;C/O LAW OFFICE OF GERALD MALISZEWSKI, P.O. BOX 270829, SAN DIEGO, CA, 92198-2829, US

(73) Assignee: Sharp Laboratories of America, Inc.

(21) Appl. No.: 11/479,221

(22) Filed: Jun. 30, 2006

Related U.S. Application Data
(63) Continuation-in-part of application No. 10/862,761, filed on Jun. 7, 2004.
Application No. 10/862,761 is a continuation-in-part of application No. 10/831,424, filed on Apr. 23, 2004, now Pat. No. 6,995,053.
(63) Continuation-in-part of application No. 10/953,913, filed on Sep. 28, 2004, now abandoned.

(51) Int. Cl. H01L 21/84; H01L 21/00

(52) U.S. Cl. 438/149

(57) ABSTRACT

A sidewall gate thin-film transistor (TFT) and associated fabrication method are provided. The method provides a substrate with a surface and forms a surface-normal feature. The surface-normal feature is normal with respect to the substrate surface, with a sidewall made from an electrical insulator. An active silicon (Si) layer is formed overlying the surface-normal feature, with a channel overlying the surface-normal feature sidewall. A gate insulator overlies the channel, and a sidewall gate overlies the gate insulator. More specifically, the gate insulator is formed from conformally depositing an electrical insulator layer overlying the active Si layer. The gate electrode layer is conformally deposited overlying the gate insulator layer and anisotropically etched, leaving a gate electrode sidewall adjacent to the gate insulator layer overlying the channel.

### RELATED APPLICATIONS

This application is a continuation-in-part of a pending patent application entitled, MULTI-PLANAR LAYOUT VERTICAL THIN-FILM TRANSISTOR INVERTER, Schuele et al., Ser. No. 10/862,761, filed Jun. 7, 2004, Attorney Docket No. SLA0875, which is a continuation-in-part of an issued patent application entitled, VERTICAL THIN FILM TRANSISTOR, invented by Schuele et al., U.S. Pat. No. 6,995,053, filed Apr. 23, 2004, Attorney Docket No. SLA0874.

This application is a continuation-in-part of a pending patent application entitled, DUAL-GATE THIN-FILM TRANSISTOR, invented by Schuele et al., Ser. No. 10/953,913, filed Sep. 28, 2004, Attorney Docket No. SLA0909.

### BACKGROUND OF THE INVENTION

1. Field of the Invention

This invention generally relates to integrated circuit (IC) fabrication and, more particularly, to a sidewall gate thin-film transistor (TFT) and associated fabrication process.

2. Description of the Related Art

The size of TFTs formed in liquid crystal display (LCD) processes is limited by the resolution of large panel photolithography tools. Currently, the resolution of feature sizes is about 0.8 microns (um) and larger. High-speed circuit operation requires a TFT capable of high drive current and low parasitic capacitance. These characteristics are obtained by shrinking the device size, especially the transistor channel length. For example, conventional production CMOS technology uses transistor channel lengths of 90 nanometers (nm), and lower, for very high-speed operation.

To further the enhancement of TFT drive currents and switching speeds, it would be desirable if the channel length of TFT devices could be made smaller than the resolution of photolithographic tools. To that end, vertical channel and dual-gate TFT devices have been developed. The co-integration of such devices, with conventional planar TFTs (with much more relaxed design rules), is anticipated to provide a technical path to the integration of a variety of circuits to address the needs of the so-called system-on-panel concept.

FIG. 1 is a partial cross-sectional view of a vertical channel (bottom gate) TFT (V-TFT), planar TFT, and dual-gate TFT (DG-TFT) on a common substrate (co-pending art). Focusing on the V-TFT device (left-most structure), the gate electrode is formed first, and the source (top) electrode basically overlaps with the gate. This overlap introduces a parasitic capacitance, which affects (decreases) the speed at which a circuit made by such device-blocks can operate. From this point of view, modifications in the basic architecture that can reduce the parasitic capacitive coupling are desirable. Such modifications must be still compatible with the concept of “co-integration”, which is the ability to simultaneously fabricate vertical and planar devices on the same substrate. Note, TOX1, TOX2, and TOX3 are oxide layers.

An additional issue affecting fabrication of V-TFT devices is the local thermal conductivity of the bottom gate structure, which affects the laser crystallization of the amorphous Si (a-Si) layer. Some prior art V-TFTs use a doped polysilicon bottom gate. The thermal conductivity of polysilicon is approximately 1.5 W/cm-K, which is two orders of magnitude greater than the thermal conductivity of SiO2 (˜0.014 W/cm-K). This high thermal conductivity leads to the undesirably rapid diffusion and dissipation of the heat in the laser irradiated Si active layer.

It would be advantageous if the active Si layer of a V-TFT could be formed overlying a three-dimensional structure having a relatively low thermal conductivity, to promote the formation of polycrystalline Si.

### SUMMARY OF THE INVENTION

The present invention describes a modified V-TFT architecture and the associated fabrication flow, which uses a SiO₂ step structure to form the V-TFT. The device architecture is suitable for improved active channel crystallization, eliminates the parasitic capacitive coupling between V-TFT gate and source/drain, and is compatible with conventional planar TFT processing, so planar and V-TFT devices can be co-integrated. Because the V-TFT uses only a top gate electrode, two masking steps for doping of the bottom gate eliminated, making the fabrication process faster and cheaper.

The vertical active silicon region can be protected from ion implantation by a spacer layer, to form an intrinsic channel region. A gate oxide and a gate electrode layer are deposited, and the gate electrode is etched anisotropically to form a spacer adjacent to the channel region prior to source/drain implant.

Accordingly, a method is providing for forming a thin-film transistor (TFT) with a sidewall gate. The method provides a substrate with a surface and forms a surface-normal feature. The surface-normal feature is normal with respect to the substrate surface, with a sidewall made from an electrical insulator. An active silicon (Si) layer is formed overlying the surface-normal feature, with a channel overlying the surface-normal feature sidewall. A gate insulator overlies the channel, and a sidewall gate overlies the gate insulator. More specifically, the gate insulator is formed by conformally depositing an electrical insulator layer overlying the active Si layer. The gate electrode layer is conformally deposited overlying the gate insulator layer and anisotropically etched, leaving a gate electrode sidewall adjacent to the gate insulator layer overlying the channel.

In one aspect, the surface-normal feature has a horizontal surface, and the active Si region is formed from conformally coating the surface-normal feature horizontal surface, sidewall, and a horizontal region adjacent to the sidewall with Si. Then, a Vth-adjust doping of the channel is performed to adjust the FET threshold voltage. The Vth-adjust doping can be performed by implanting dopant through an overlying screen oxide layer. Alternately, a doped material such as boronsilicate glass (BSG) is deposited over the active Si layer, and an annealing is performed. In another aspect, the Vth-adjust doping is performed by vertically implanting dopant into the a-Si and laterally diffusing the implanted dopant during a laser annealing process to crystallize the active Si layer.

Typically, the substrate is a temperature sensitive material such as glass, and a basecoat layer is formed overlying the substrate, made from a material such as silicon dioxide or a three-layer stack of silicon dioxide/silicon nitride/silicon dioxide. The surface-normal feature can be formed over the silicon dioxide basecoat, or formed by etching the top layer of the three-layer stack basecoat.

Additional details of the above-described method and a sidewall gate TFT device are described in more detail below.

### BRIEF DESCRIPTION OF THE DRAWINGS

FIG. 1 is a partial cross-sectional view of a vertical channel (bottom gate) TFT (V-TFT), planar TFT, and dual-gate TFT (DG-TFT) on a common substrate (co-pending art).

FIG. 2 is a partial cross-sectional view of a thin-film transistor (TFT) with a sidewall gate.

FIG. 3 is a partial cross-sectional view of the sidewall gate TFT, made from a three-layer stack basecoat layer.

FIG. 4 is a partial cross-sectional view of a channel formation ion implantation process.

FIG. 5 is a partial cross-sectional view of a source/drain implantation process.

FIGS. 6A and 6B are partial cross-sectional views depicting the completion of fabrication Steps 1-4.

FIG. 7 is a partial cross-sectional view of the device of FIG. 6A or 6B, after the patterning of silicon islands in Step 9.

FIG. 8 is a plan view of the patterns used for planar and sidewall gate V-TFT devices.

FIG. 9 is a partial cross-sectional view of the devices of FIG. 8, after the gate etch.

FIG. 10 is a partial cross-sectional view of the devices of FIG. 9 showing separate V-TFT and planar TFT LDD implants.

FIG. 11 is a partial cross-sectional view depicting the devices of FIG. 10 following the implantations described in Step 17.

FIG. 12 is a cross-sectional view of a completed sidewall gate V-TFT and planar TFT.

FIGS. 13A and 13B are flowcharts illustrating a method for forming a TFT with a sidewall gate.

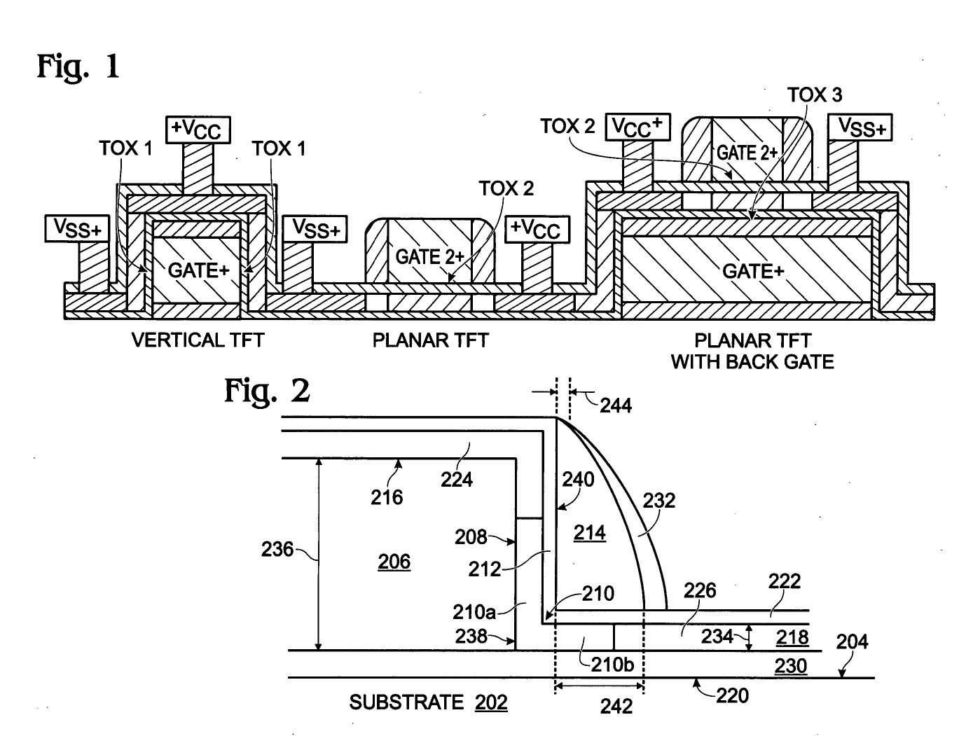

### DETAILED DESCRIPTION

FIG. 2 is a partial cross-sectional view of a thin-film transistor (TFT) with a sidewall gate. The sidewall gate TFT 200 comprises a substrate 202 with a surface 204. A surface-normal feature 206, normal with respect to the substrate surface 204, has a sidewall 208 made from an electrical insulator. For example, the insulator may be silicon oxide or a silicon nitride material. Although the surface-normal feature is depicted here as a step, in other variations (not shown) the surface-normal feature can be a via, cavity, pillar, or the like. Further, although the feature 206 is shown as orthogonal to the substrate surface 204, in other aspects (not shown), the feature 206 may be formed at an angle with respect to the surface, as might be realistically expected using an etching process, which typically removes more from the top of a feature than the foot of a feature. Further, the sidewall may have a bowed or tapered shape. In fact, the surface normal feature is not limited to any particular topology, as long as a spacer gate feature can be formed, which in turn protects the channel region from source/drain implantation.

A channel 210 overlies the surface-normal feature sidewall 208. A gate insulator 212 overlies the channel 210, and a sidewall gate 214 overlies the gate insulator 212. In some aspects as shown, the channel 210 is L-shaped, having a vertical portion 210a and an horizontal portion 210b.

The surface normal feature 206 has a horizontal surface 216. The channel 210 is formed in an active silicon (Si) layer 218 conformally covering the surface-normal feature horizontal surface 216 and sidewall 208, and a horizontal substrate region 220, adjacent the surface-normal feature sidewall 208. The gate insulator 212 is a portion of an electrical insulator layer 222 conformally covering the active Si layer 218. A first source/drain (S/D) region 224 is formed in the active Si layer 218 overlying the surface-normal feature horizontal surface 216. A second S/D region 226 is formed in the active Si layer 218 adjacent to the surface-normal feature sidewall 208, overlying horizontal substrate region 220. For simplicity, the above discussion assumes that the sidewall 208 has a vertical face and that the substrate as a horizontal surface. However, these labels are relative and do not necessarily limit the invention.

In one aspect, the substrate 202 is a material such as glass, plastic, or quartz. These materials are temperature sensitive, and are known to degrade when exposed to process temperatures exceeding 600° C. In this aspect, a basecoat layer 230 may overlie the substrate 202. For example, the basecoat 230 can be an insulator such as silicon dioxide, and the surface normal feature 206 can be formed over the basecoat layer 230 through conventional deposition and selective etching processes. An electrical insulator sidewall 232 optionally overlies the sidewall gate 214 (as shown). In one aspect, the substrate 202 is a temperature sensitive material such as glass, plastic, or quartz. The surface-normal feature 206 is a material such as silicon oxide with a first thermal conductivity, and the active Si layer 218 has a second thermal conductivity greater than the first thermal conductivity. As notes earlier, this difference in thermal conductivity is conducive to formation of polysilicon during the laser annealing process.

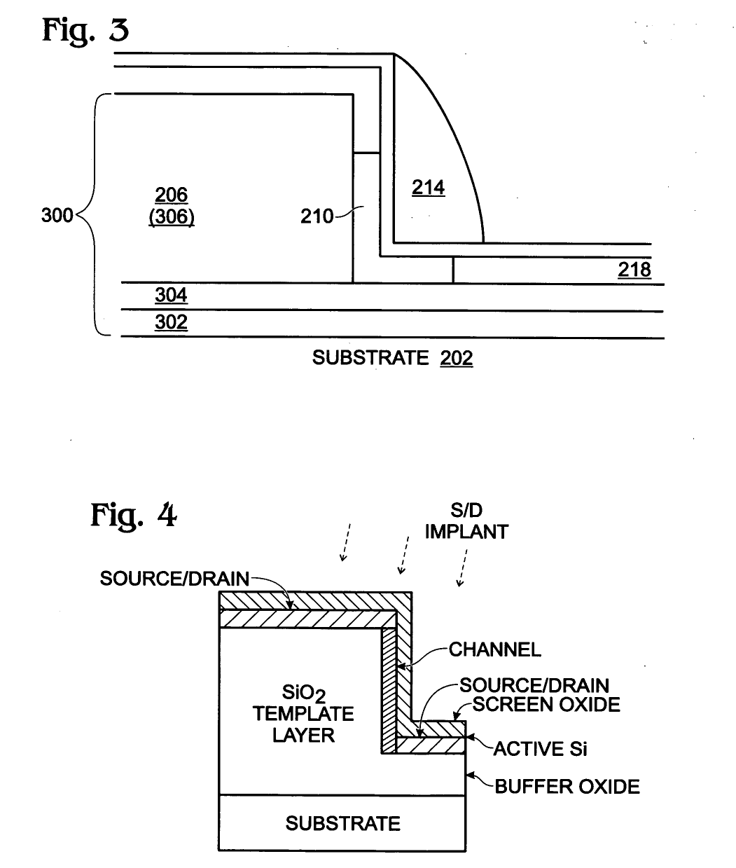

FIG. 3 is a partial cross-sectional view of the sidewall gate TFT, made from a three-layer stack basecoat layer. The three-layer basecoat stack 300 is comprised of a layer of silicon dioxide 302, overlaid with a layer of silicon nitride 304, overlaid with a layer of silicon dioxide 306. In this aspect, the surface-normal feature 206 is formed in the silicon dioxide top layer 306 of the three-layer stack 300.

Returning to FIG. 2, although the following discussion applies equally well to FIG. 3, the active Si layer 218 is polycrystalline Si having a thickness 234 in a range from about 300 to 1000 Å. Alternately, the active Si layer 218 can be amorphous Si (a-Si) having a thickness 234 in a range from about 300 to 1000 Å. In one aspect, the surface-normal feature sidewall 208 has a height 236 in a range of about 100 to 500 nanometers (nm), and a foot 238. The sidewall gate 214 has a face 240 adjacent the gate insulator 212, and a first width 242 in a range of about 100 to 500 nanometers adjacent the surface-normal feature sidewall foot 238. The sidewall gate 214 tapers to a second width 244, less than the first width 242. Here, the second width 244 is shown as about zero.

In another aspect, the surface-normal feature 208 has a thermal conductivity, which is less than the thermal conductivity of either the active Si layer 218 or the sidewall gate 214. The sidewall gate 214 can be made from doped, intrinsic, or in-situ-doped polysilicon. In other aspects, the sidewall gate 214 is a high temperature metal such as W or Ta. Alternately, the sidewall gate 214 can be a conductive nitride such as WN, TaN, or TiN. However, the gate is not necessarily limited to this list of exemplary materials.

### Functional Description

The present invention use a SiO₂ step (surface-normal) structure to form a V-TFT, to improve active channel crystallization, eliminating the parasitic capacitive coupling between gate and source/drain, which may occur in bottom gate V-TFTs. The sidewall gate V-TFT fabrication is also compatible, and may be co-integrated with conventional planar TFT processing.

FIG. 4 is a partial cross-sectional view of a channel formation ion implantation process. A vertical face is etched in a suitable template material (such as SiO₂ or Si₃N₄) to form a surface-normal feature. A spacer is formed by a conformal screening layer. The spacer prevents doping of the back of the active channel by ions which are slightly off axis. At this point there is no gate electrode to form a transistor.

FIG. 5 is a partial cross-sectional view of a source/drain implantation process. A gate oxide and a gate electrode layer are deposited, and the gate electrode is etched anisotropically to form a spacer adjacent the channel region. The spacer acts as a gate electrode and also prevents the doping of the back of the active channel by ions, which are slightly off axis.

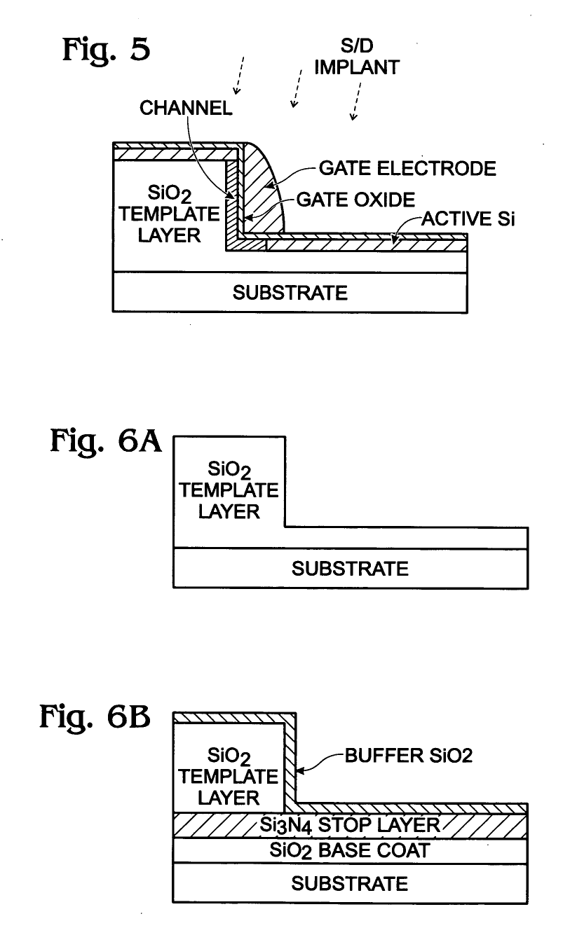

FIGS. 6A and 6B are partial cross-sectional views depicting the completion of fabrication Steps 1-4. A detailed explanation of the sidewall gate V-TFT and planar TFT co-integration is described as follows:

1. Start with the appropriate substrate (e.g., glass).

2. Deposit a basecoat layer to isolate the TFT plane from the substrate. The basecoat layer may be a single layer (i.e., ˜200-300 nm of SiO₂), as shown in FIG. 6A, or a layer-stack (i.e. 0˜250 nm SiO₂/10-100 nm Si₃N₄/30-200 nm SiO₂), as shown in FIG. 6B. The three-layer stack top SiO₂ layer thickness is chosen to control the channel length of the sidewall gate V-TFT, and a middle layer of Si₃N₄ is used as an etch stop layer, which is particularly advantageous for precise control of the device size.

3. The top oxide layer is patterned (Mask 1) and plasma etched to form a vertical step (surface-normal feature) of 100 nm to 500 nm.

4. Optionally, a thin buffer oxide layer may be deposited to improve isolation between the channel and the substrate (see FIG. 6B).

5. An amorphous silicon layer, 300 to 1000 Å thick, is deposited to form the transistor active channel.

6. Channel Vₜₕ-adjust implant can be carried out at this time. This implant may be accomplished by means of an angled implant to ensure that dopant species are implanted in the back of the active channel. Alternatively, an auto-doping process may be used, via the deposition of a doped-oxide layer (i.e. BSG/PSG) and subsequent rapid annealing to diffuse B or P to the Si layer under the doped-oxide film. Another possibility is regular implantation (not angled) of the appropriate species followed by lateral diffusion during the subsequent crystallization step (Step 8).

7. Furnace anneal the structure to drive off the hydrogen in the amorphous silicon layer.

8. Laser-anneal the active silicon layer.

9. Pattern Si islands with photoresist and plasma etch (Mask 2).

FIG. 7 is a partial cross-sectional view of the device of FIG. 6A or 6B, after the patterning of silicon islands in Step 9.

10. Clean the a-Si surface and deposit a gate oxide layer, which serves as the gate oxide of the V-TFT and the planar devices. Typically, the gate oxide layer is a 30-100 nm thick SiO₂ film. Many possible methods can be used to deposit the oxide, including:

a. Plasma-enhanced chemical vapor deposition (PECVD) SiO₂ deposition, especially TEOS oxide (for thicknesses >100 Å). This process may include an additional (post-deposition) plasma oxidation step using a high-density plasma (HDP).

b. PECVD or low pressure CVD (LPCVD) silicon nitride.

c. Inductively-coupled plasma (ICP) (or other HDP) oxidation of the exposed polysilicon active Si layer surface.

d. Combinations of the above processes.

Whatever process is used, it is desirable that the gate oxide layer have good step coverage, low leakage current, high breakdown field, and low density of interface states.

11. Optionally, a dual thickness gate oxide process can be used to produce thick gate oxide for planar TFTs and a thin oxide for the sidewall gate V-TFT. The dual thickness gate oxide is formed from the first oxide described in Step 10, and a second oxide described below:

After the gate oxide deposition of Step 10, cover the planar TFT area with photoresist and etch the gate oxide in regions where sidewall gate V-TFTs are to be formed.

Strip the photoresist and clean the surface using a RCA cleaning.

Deposit a thin (second) gate oxide for the sidewall gate V-TFT.

This dual thickness gate oxide process may be used to produce fast V-TFT devices operating at low voltage, co-integrated with high voltage planar devices, which can be used for LCD drivers for example.

12. Deposit a second Si layer (typically 200 nm poly-Si). This layer serves as the gate electrode of the planar and sidewall gate V-TFT devices.

13. Optionally dope the Si gate electrode layer (n-type and p-type depending on the device for CMOS integration using Masks 3 & 4). The gates are also doped after gate patterning during the source/drain implantation. However, the source/drain implants are shallow so there is a possibility that gate doping will be low at the gate oxide interface, causing gate depletion effects which decrease TFT performance.

a) For N channel (NMOS) devices with a 200 nm thick poly active Si layer, implant phosphorus with a dosage of about 3e15 and an energy of about 60 keV

b) For P channel (PMOS) devices with a 200 nm thick poly active Si layer, implant boron at about 5e15/28 keV.

14. Pattern the gate layer (Mask 5). The etching process needs to be conducted in a way that enables the formation of a sidewall-type gate for the vertical devices. At the same time, the photoresist pattern is used to form the planar TFT gates and landing pads for contacts to the V-TFT sidewall gate.

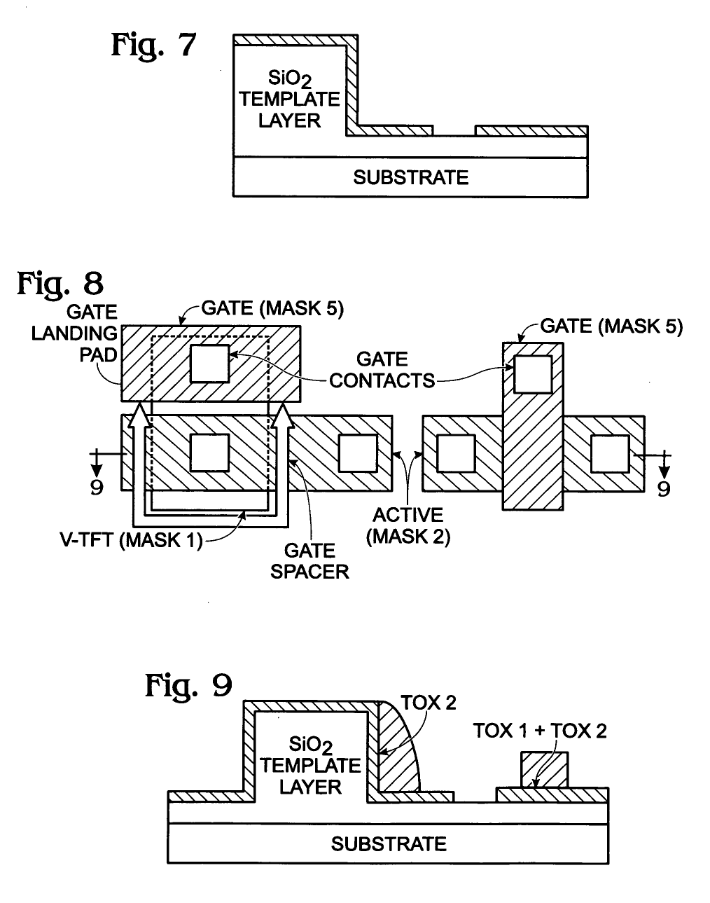

FIG. 8 is a plan view of the patterns used for planar and sidewall gate V-TFT devices. Note, the sidewall gate (gate spacer) is connected to the gate contact via the gate landing pad.

FIG. 9 is a partial cross-sectional view of the devices of FIG. 8, after the gate etch.

15. Low dose LDD implants can be carried out at this time for V-TFTs with a dosage between about 5e12 and 5e13 ions/cm² and an energy level sufficient to penetrate to a depth greater than the sum of the Tox1+active layer, and less than the sum of Tox1+active layer+Tox3. A second LDD implant is carried out for the planar TFT with a lower energy to place the peak of the implant distribution in the a-Si layer. Typically, the LDD implant will be used only for NMOS devices (Mask 6) but a separate P-LDD can be performed using a second photo mask/implant step (Mask 7).

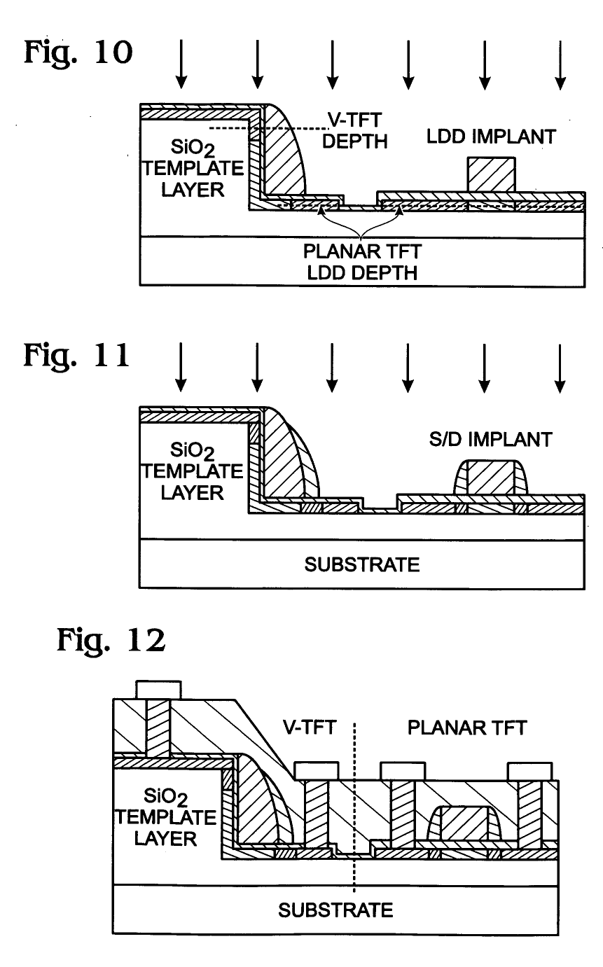

FIG. 10 is a partial cross-sectional view of the devices of FIG. 9 showing separate V-TFT and planar TFT LDD implants.

16. Form sidewalls in planar TFTs using combination of SiO₂ deposition and etching steps. Typical, the (total) SiO₂ thickness (on top of the planar TFT topography) is of the order of 300 nm for a target sidewall width of ˜0.15-0.18 micrometers (μm).

17. Implant N+ and P+ source drain regions separately using. photoresist to protect devices of the opposite type (Masks 7 and 8).

a) For N channel devices, implant phosphorus at about 3e 15/25 keV.

b) For P channel devices, implant boron at about 5e 15/12 keV.

FIG. 11 is a partial cross-sectional view depicting the devices of FIG. 10 following the implantations described in Step 17.

18. Deposit screen oxide (e.g., 500 Å thick TEOS SiO₂).

19. Anneal the structure at about 600-700° C. for 1 to 10 hours, to finish dopant activation.

20. The active silicon and poly gate surfaces can be silicided using a self-aligned process at this point, but salicide is not required. Briefly the salicide process is as follows:
Etch to remove the screening oxide layer, stopping on the silicon.
Deposit metal (e.g., Ti, NI or Co) for silicide.
Anneal to form silicide.
Peroxide-based wet etch to remove un-reacted metal.
Anneal to stabilize the silicide.

FIG. 12 is a cross-sectional view of a completed sidewall gate V-TFT and planar TFT. After Step 20 a conventional back end process flow can be followed for isolation, contacts, and metal interconnections.

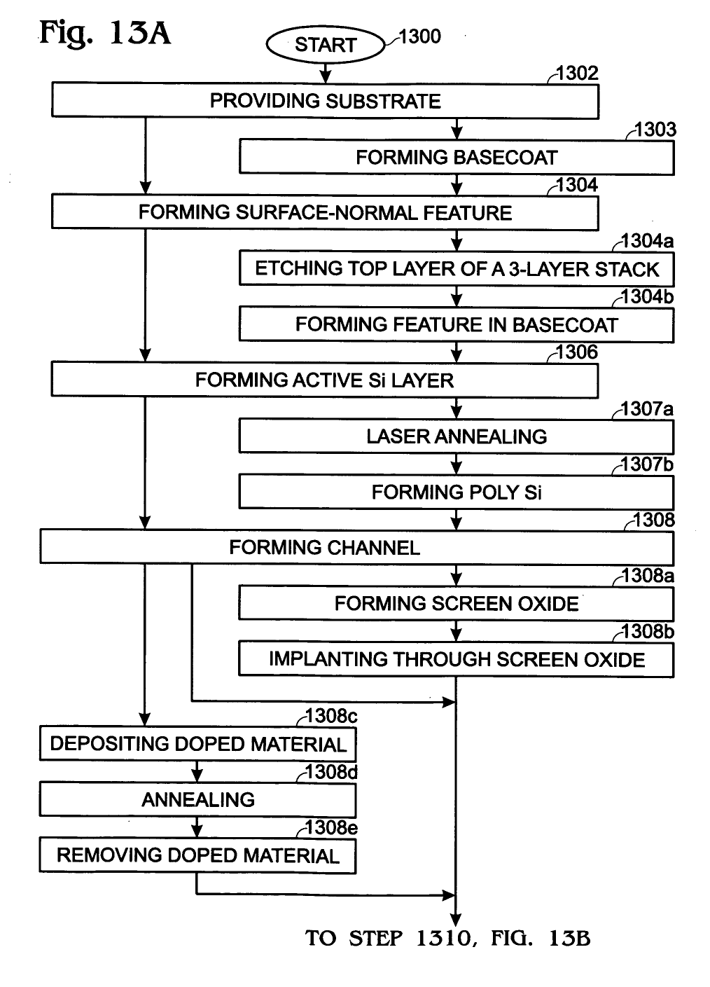

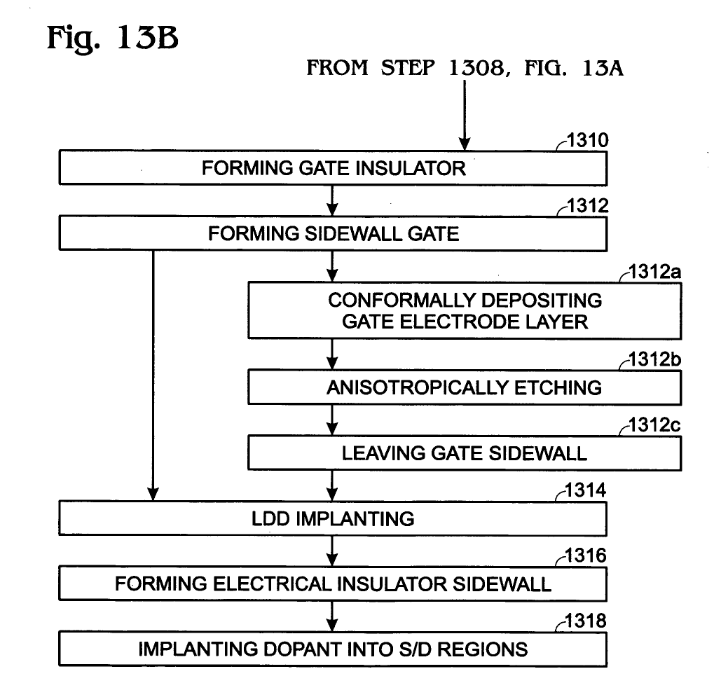

FIGS. 13A and 13B are flowcharts illustrating a method for forming a TFT with a sidewall gate. Although the method is depicted as a sequence of numbered steps for clarity, the numbering does not necessarily dictate the order of the steps. It should be understood that some of these steps may be skipped, performed in parallel, or performed without the requirement of maintaining a strict order of sequence. The method starts at Step 1300.

Step 1302 provides a substrate with a surface. Step 1304 forms a surface-normal feature, normal with respect to the substrate surface, with a sidewall made from an electrical insulator. Step 1306 forms an active Si layer overlying the surface-normal feature. Step 1308 forms a channel overlying the surface-normal feature sidewall. Step 1310 forms a gate insulator overlying the channel. Step 1312 forms a sidewall gate overlying the gate insulator.

In one aspect, forming the surface-normal feature in Step 1304 includes forming a surface-normal feature with a horizontal surface, and forming the active Si region in Step 1306 includes conformally coating the surface-normal feature horizontal surface, sidewall, and a horizontal region adjacent to the sidewall with Si. Then, forming the channel in Step 1308 includes Vth-adjust doping a region of the active Si region overlying the sidewall. For example, Step 1308a may form a screen oxide layer overlying the active Si layer, and Step 1308b implants dopant through the screen oxide layer. Alternately, Step 1308c deposits a doped material such as boronsilicate glass (BSG) or phosphosilicate glass (PSG) overlying active Si layer. Step 1308d anneals, and Step 1308e removes the doped material.

In another aspect, forming the gate insulator in Step 1310 includes conformally depositing an electrical insulator layer overlying the active Si layer. Then, the sidewall gate in Step 1312 includes substeps. Step 1312a conformally deposits a gate electrode layer overlying the gate insulator layer. Step 1312b anisotropically etches the gate electrode layer. Step 1312c leaves a gate electrode sidewall adjacent to the gate insulator layer overlying the channel in response to the etching.

In another aspect, forming the substrate in Step 1302 includes forming a substrate from a material such as glass, plastic, quartz, or a temperature sensitive material. Then, Step 1303 forms a basecoat layer overlying the substrate, made from a material such as silicon dioxide or a three-layer stack of silicon dioxide/silicon nitride/silicon dioxide. If the basecoat is formed from the three-layer stack, then forming the surface-normal feature in Step 1304 may include substeps. Step 1304a selectively etches the silicon dioxide top layer of the three-layer stack. Step 1304b forms a silicon dioxide feature in the basecoat layer.

In one aspect, forming the active Si layer in Step 1306 includes depositing a layer of amorphous Si (a-Si), having a thickness in a range from about 300 to 1000 A. Optionally, Step 1307a laser anneals the a-Si, and Step 1307b forms polycrystalline Si. In this aspect, the Vth-adjust doping of Step 1308 may be performed by vertically implanting dopant into the a-Si, and laterally diffusing the implanted dopant during the laser annealing process (Step 1307a).

Step 1314, following the formation of the sidewall gate in Step 1312, low dose (LDD) implants dopant at an angle about orthogonal to the surface-normal feature horizontal surface, into the sidewall gate, first S/D region, and second S/D region. In one aspect, Step 1316 forms an electrical insulator sidewall overlying the sidewall gate, and Step 1318 implants dopant into the first and second S/D regions.

In another aspect, forming the surface-normal feature in Step 1304 includes forming a surface-normal feature with a first thermal conductivity. Forming the active Si layer in Step 1306 includes forming a layer having a second thermal conductivity greater than the first thermal conductivity.

A sidewall gate V-TFT and associated fabrication processes have been described. Examples of some specific structures, materials, and fabrication processes have been presented to illustrate the invention. However, the invention is not limited to merely these examples. Other variations and embodiments of the invention will occur to those skilled in the art.

We claim:

1. A method for forming a thin-film transistor (TFT) with a sidewall gate, the method comprising:
providing a substrate with a surface;
forming a surface-normal feature, normal with respect to the substrate surface, with a sidewall made from an electrical insulator;
forming an active silicon (Si) layer overlying the surface-normal feature;
forming a channel overlying the surface-normal feature sidewall;
forming a gate insulator overlying the channel; and,
forming a sidewall gate overlying the gate insulator.

2. The method of claim 1 wherein forming the surface-normal feature includes forming a surface-normal feature with a horizontal surface;
wherein forming the active Si region includes conformally coating the surface-normal feature horizontal surface, sidewall, and a horizontal region adjacent to the sidewall with Si; and,
wherein forming the channel includes Vₜₕ-adjust doping a region of the active Si region overlying the sidewall.

3. The method of claim 2 wherein Vₜₕ-adjust doping the region of the active Si region overlying the sidewall includes:
forming a screen oxide layer overlying the active Si layer; and,
implanting dopant through the screen oxide layer.

4. The method of claim 2 wherein Vₜₕ-adjust doping the region of the active Si region overlying the sidewall includes:
depositing a doped material selected from a group including boronsilicate glass (BSG) and phosphosilicate glass (PSG) overlying active Si layer;
annealing; and,
removing the doped material.

5. The method of claim 1 wherein forming the gate insulator includes conformally depositing an electrical insulator layer overlying the active Si layer;
wherein forming the sidewall gate includes:
conformally depositing a gate electrode layer overlying the gate insulator layer;
anisotropically etching the gate electrode layer; and,
in response to the etching, leaving a gate electrode sidewall adjacent to the gate insulator layer overlying the channel.

6. The method of claim 2 wherein forming the substrate includes forming a substrate from a material selected from a group consisting of glass, plastic, and quartz; and,
the method further comprising:
forming a basecoat layer overlying the substrate, made from a material selected from a group consisting of silicon dioxide and a three-layer stack of silicon dioxide/silicon nitride/silicon dioxide.

7. The method of claim 6 wherein forming the basecoat layer includes forming the three-layer stack; and,
wherein forming the surface-normal feature includes:
selectively etching the silicon dioxide top layer of the three-layer stack; and,
forming a silicon dioxide feature in the basecoat layer.

8. The method of claim 1 wherein forming the active Si layer includes depositing a layer of amorphous Si (a-Si), having a thickness in a range from about 300 to 1000 Å.

9. The method of claim 6 wherein forming the active Si layer includes:
depositing a layer of a-Si, having a thickness in a range from about 300 to 1000 Å;
laser annealing the a-Si; and,
forming polycrystalline Si.

10. The method of claim 9 wherein Vₜₕ-adjust doping the region of the active Si region overlying the sidewall includes:
vertically implanting dopant into the a-Si; and,
laterally diffusing the implanted dopant during the laser annealing process.

11. The method of claim 2 further comprising:
following the formation of the sidewall gate, low dose (LDD) implanting dopant at an angle about orthogonal to the surface-normal feature horizontal surface, into the sidewall gate, first S/D region, and second S/D region.

12. The method of claim 11 further comprising:
forming an electrical insulator sidewall overlying the sidewall gate; and,
implanting dopant into the first and second S/D regions.

13. The method of claim 1 wherein forming the substrate includes forming a substrate from a material selected from a group consisting of glass, plastic, and quartz;
wherein forming the surface-normal feature, with the sidewall made from the electrical insulator includes forming a surface-normal feature with a first thermal conductivity; and,
wherein forming the active Si layer includes forming a layer having a second thermal conductivity greater than the first thermal conductivity.

14. A thin-film transistor (TFT) with a sidewall gate, the sidewall gate TFT comprising:
a substrate with a surface;
a surface-normal feature, normal with respect to the substrate surface, with a sidewall made from an electrical insulator;
a channel overlying the surface-normal feature sidewall;
a gate insulator overlying the channel; and,
a sidewall gate overlying the gate insulator.

15. The sidewall gate TFT of claim 14 wherein the surface normal feature has a horizontal surface;
wherein the channel is formed in an active silicon (Si) layer conformally covering the surface-normal feature horizontal surface and sidewall, and a horizontal substrate region, adjacent the surface-normal feature sidewall; and,
wherein the gate insulator is an electrical insulator layer conformally covering the active Si layer.

16. The sidewall gate TFT of claim 15 further comprising:
a first source/drain (S/D) region formed in the active Si layer overlying the surface-normal feature horizontal surface; and
a second S/D region in the active Si layer adjacent to the surface-normal feature sidewall.

17. The sidewall gate TFT of claim 16 wherein the substrate is a material selected from a group consisting of glass, plastic, and quartz; and,
the sidewall gate TFT further comprising:
a basecoat layer overlying the substrate, made from a material selected from a group consisting of silicon dioxide and a three-layer stack of silicon dioxide/silicon nitride/silicon dioxide.

18. The sidewall gate TFT of claim 17 wherein the basecoat layer is the three-layer stack; and,
wherein the surface-normal feature is formed in the silicon dioxide top layer of the three-layer stack.

19. The sidewall gate TFT of claim 17 wherein the active Si layer is polycrystalline Si having a thickness in a range from about 300 to 1000 Å.

20. The sidewall gate TFT of claim 14 wherein the active Si layer is amorphous Si (a-Si) having a thickness in a range from about 300 to 1000 Å.

21. The sidewall gate TFT of claim 14 further comprising:
an electrical insulator sidewall overlying the sidewall gate.

22. The sidewall gate TFT of claim 14 wherein the surface-normal feature sidewall has a height in a range of about 100 to 500 nanometers (nm).

23. The sidewall gate TFT of claim 14 wherein the surface-normal feature sidewall has a foot; and,
wherein the sidewall gate has a face adjacent the gate insulator, and a first width in a range of about 100 to 500 nanometers adjacent the surface-normal feature sidewall foot, tapering to a second width, less than the first width.

24. The sidewall gate of claim 14 wherein the substrate is a material selected from a group consisting of glass, plastic, and quartz; and,
wherein the surface-normal feature has a first thermal conductivity; and,
wherein the active Si layer has a second thermal conductivity greater than the first thermal conductivity.
